(19) United States
(12) Patent Application Publication
(10) Pub. No.: US 2008/0282128 A1
(43) Pub. Date: Nov. 13, 2008

(54) Method of Error Correction Code on Solid State Disk to Gain Data Security and Higher Performance

(75) Inventors: Charles Chung Lee, Cupertino, CA (US); David Queichang Chow, San Jose, CA (US); Abraham Chih-Kang Ma, Fremont, CA (US); I-Kang Yu, Palo Alto, CA (US); Ming-Shiang Shen, Hsin Chuang (TW)

Correspondence Address: LAW OFFICES OF IMAM, 111 N. MARKET STREET, SUITE 1010, SAN JOSE, CA, 95113, US

(73) Assignee: SUPER TALENT ELECTRONICS, INC., San Jose, CA (US)

(21) Appl. No.: 11/932,461

(22) Filed: Oct. 31, 2007

Related U.S. Application Data
(63) Continuation-in-part of application No. 11/864,671, filed on Sep. 28, 2007.
Application No. 11/864,671 is a continuation-in-part of application No. 11/466,759, filed on Aug. 23, 2006.
Application No. 11/466,759 is a continuation-in-part of application No. 11/624,667, filed on Jan. 18, 2007.
Application No. 11/624,667 is a division of application No. 09/478,720, filed on Jan. 6, 2000, now Pat. No. 7,257,714.
Application No. 09/478,720 is a continuation-in-part of application No. 09/366,976, filed on Aug. 4, 1999, now Pat. No. 6,547,130.

(51) Int. Cl. H03M 13/07; G06F 11/10; H03M 13/21

(52) U.S. Cl. 714/755; 714/793; 714/E11.032

(57) ABSTRACT

An electronic data storage device having a Reed Solomon (RS) decoder including a syndrome calculator block responsive to information including data and overhead and operative to generate a syndrome, in accordance with an embodiment of the present invention. The electronic data storage device further includes a root finder block coupled to receive said syndrome and operative to generate at least two roots, said RS decoder for processing said two roots to generate at least one error address identifying a location in said data wherein said error lies; and an erasure syndrome calculator block responsive to said information and operative to generate an erasure syndrome, said RS decoder responsive to said information identifying a disk crash, said RS decoder for processing said erasure syndrome to generate an erasure error to recover the data in said disk crash.

### CROSS REFERENCE TO RELATED APPLICATION

This application is a continuation-in-part (CIP) of the co-pending application “Electronic Data Flash Card with Various Flash Cells”, U.S. application Ser. No. 11/864,671 filed Sep. 28, 2007, which is a CIP of “Flash Memory Controller for Electronic Data Flash Card”, U.S. application Ser. No. 11/466,759 filed Aug. 23, 2006.

This application is also a continuation-in-part (CIP) of the co-pending application for “Electronic Data Storage Medium with Fingerprint Verification Capability”, U.S. Ser. No. 11/624,667 filed Jan. 18, 2007, which is a divisional application of U.S. patent application Ser. No. 09/478,720, filed on Jan. 6, 2000, which has been petitioned to claim the benefit of CIP status of one of inventor's earlier U.S. patent applications for “Integrated Circuit Card with Fingerprint Verification Capability”, U.S. application Ser. No. 09/366,976, filed Aug. 4, 1999, now issued as U.S. Pat. No. 6,547,130.

### BACKGROUND OF THE INVENTION

1. Field of the Invention

The present invention relates generally to the field of solid state flash disks and particularly to a method and apparatus for providing error detection and recovery on solid state disks.

2. Description of the Prior Art

Flash memory storage disk is gaining more in popularity as consumers look for more compact and versatile means of storing information. Solid state disk (SSD) can be organized by several storage units called solid state array being linked together where the disks may be identical in size or have different sizes but will be allowed to have a minimum capacity. Total capacity of SSD may be the total of all disk capacities being summed together for fast performance but without disk recovery capacity. To ensure data correctness by fault-tolerant feature, an overhead should be involved for adding parity byte operation.

However, as density of flash chips is increasing defect and fail rate are also increasing especially when Multi-Level Cell (MLC) technology is introduced in the flash manufacturing process even though most of the SSD are made from Single-Level Cell (SLC) process flash chips.

Reed Solomon (RS) algorithm is popularly applied in industrial applications for error detection and recovery. Prior art methods to find roots of error polynomial include Berlekamp-Messay and Euclidean methods after which Chien's method is applied to search for error locations. However, since implementation requires complex hardware and lengthy calculations, cost of error correction code (ECC) is higher using the above prior art methods.

A second method utilizes look up table. A pre-calculated value is stored in Read Only Memory (ROM) for error searching. Advantage of this method is the speed and substantial time saved for calculations, however, for long size codes ROM could occupy expensive silicon areas and directly increase controller chip cost.

Normally, four procedures are involved in Reed Solomon decoding process:
(1) Syndrome calculation: Each syndrome is calculated based on read out of data from each flash memory disk, a non-zero value determines the error numbers since correct byte value in each disk will yield zero value.
(2) Error location polynomial calculation in order to find out the polynomial coefficient.
(3) Root find based on error location polynomial.
(4) Reciprocal of root to determine the error location of read out strings.
(5) Use of syndrome value and error location polynomial coefficient to find out error values associated with each error location.
(6) Recover original strings of value and return the 512 bytes of sector data to the requesting unit.

Procedure (2) above normally uses Berlekamp-Messay recursive method or Euclidean matrix method the complexity of which depends on the code length independently of error numbers. Procedure (3) to find roots of error polynomial adopts Chien's searching method with a calculation time depending on the code length.

The above two methods do not fully utilize the characteristic of low error counts of flash memory disk and requires sophisticated hardware and relatively long calculation time.

It is therefore desirable to develop a method and procedure for performing disk crash (erasure) calculations which can save hardware cost of silicon area ROM look up while eliminating lengthy calculations based on Chien's searching algorithm. In addition, the new method should only depend on the syndrome result to find out error location which is the most difficult process in the RS algorithm.

### SUMMARY OF THE INVENTION

Briefly, an embodiment of the present invention includes an electronic data storage device having a Reed Solomon (RS) decoder including a syndrome calculator block responsive to information including data and overhead and operative to generate a syndrome. The electronic data storage device further includes a root finder block coupled to receive said syndrome and operative to generate at least two roots, said RS decoder for processing said two roots to generate at least one error address identifying a location in said data wherein said error lies; and an erasure syndrome calculator block responsive to said information and operative to generate an erasure syndrome, said RS decoder responsive to said information identifying a disk crash, said RS decoder for processing said erasure syndrome to generate an erasure error to recover the data in said disk crash.

The foregoing and other objects, features and advantages of the present invention will be apparent from the following detailed description of the preferred embodiments which make reference to several figures of the drawing.

### IN THE DRAWINGS

FIG. 1(a) shows an electronic data storage device 10 coupled to a host device 12, in accordance with an embodiment of the present invention.

FIG. 1(b) shows four storage disks or solid disk arrays (SDA), 54-60, for storing data and four Reed Solomon (RS) parity disks 62-70 for storing overhead including the RS parity bytes, in accordance with an embodiment of the present invention.

FIG. 2 shows an RS calculation unit 21 including an RS encoder 86 and an RS decoder 88, in accordance with an embodiment of the present invention.

FIG. 3 shows two flowcharts 140 and 142 for write and read processes, respectively, for an electronic data storage device, in accordance with an embodiment of the present invention.

FIG. 4(a) shows a block diagram 220 of an RS encoder in a write process and a main memory 224, in accordance with an embodiment of the present invention.

FIG. 4(b) shows a block diagram of an RS decoder 250 in the read direction, in accordance with an embodiment of the present invention.

FIG. 5(a) shows a write operation block diagram 199, in accordance with an embodiment of the present invention.

FIG. 5(b) shows a read operation block diagram 305, in accordance with an embodiment of the present invention.

FIG. 6 shows the RS decoder 350 including an erasure block 352, a syndrome calculate block 358, a root polynomial calculator 364, an error value calculator block 370, an error syndrome calculator block 376, an erasure root finder block 382, an erasure polynomial block 384 and an erasure error calculator block 386, in accordance with an embodiment of the present invention.

FIG. 7 shows an exemplary embodiment of the block 360, in accordance with an embodiment of the present invention.

FIG. 8 shows further details of the block 412 of the example of FIG. 7, in accordance with an embodiment of the present invention.

FIG. 9 shows a flowchart of the steps performed in recovering data, in accordance with one method of the present invention.

### DETAILED DESCRIPTION OF THE PREFERRED EMBODIMENTS

In one embodiment of the present invention, a Reed Solomon (RS) error detection and correction (ECC) or coding and decoding method is used in conjunction with non-volatile memory with disk crash (erasure) calculations capability which in turn simplifies the circuitry employed. Simplification in circuitry results in hardware costs of silicon area read only memory (ROM) look up. Other advantages of the present invention include eliminating lengthy calculations based on Chien's searching algorithm.

The embodiment of the present invention is based on low error count characteristic of solid state disk (SSD) storage disk array for only two or less error counts per codeword. A relatively simple method depending on syndrome result is needed to find error location which is the most part of the RS algorithm. In addition. The present invention uses the knowledge of disk crash (erasure) as a pre-known condition to inform the RS controller that the error location is known whence does not need to be found by the RS controller. Thus error recovery capability is enhanced by fully utilizing the pre-known disk crash knowledge. Additional advantages of the present invention include simple RS logic design structure, reduced hardware complexity, simpler control signal handling, faster speed and not being influenced by the code length.

Two-error counts format RS code based on Galois Field (GF) (2⁸) is used in the embodiment of the present invention wherein each symbol or byte is 8 bits. Also N is the code length and 4<N≦255, N−4 is the length of message unit which is the read out code in the data area of flash memory, 4 bytes comprise the parity bytes generated from the RS encoder to correct up to two errors per codeword.

If s denotes error bytes and r denotes the number of disk crash or erasure then 2s+r≦2t. Since the parity bytes are four then 2t=4 and from the above inequality it follows that the total error bytes may be 2, i.e. s=2. However, with only one error byte, i.e. s=1, up to disk crashes (erasure cases) may be corrected by the RS encoder/decoder.

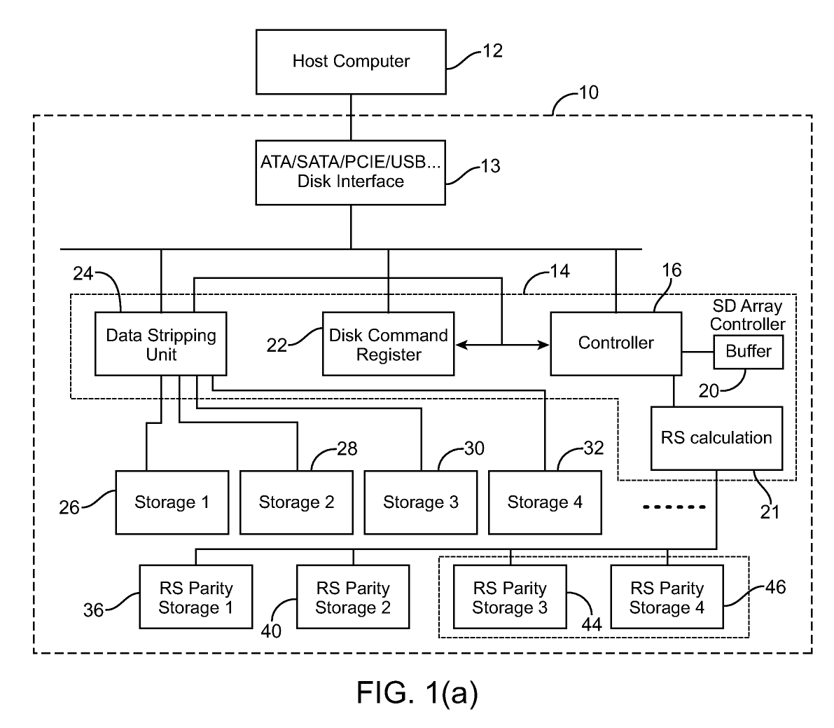

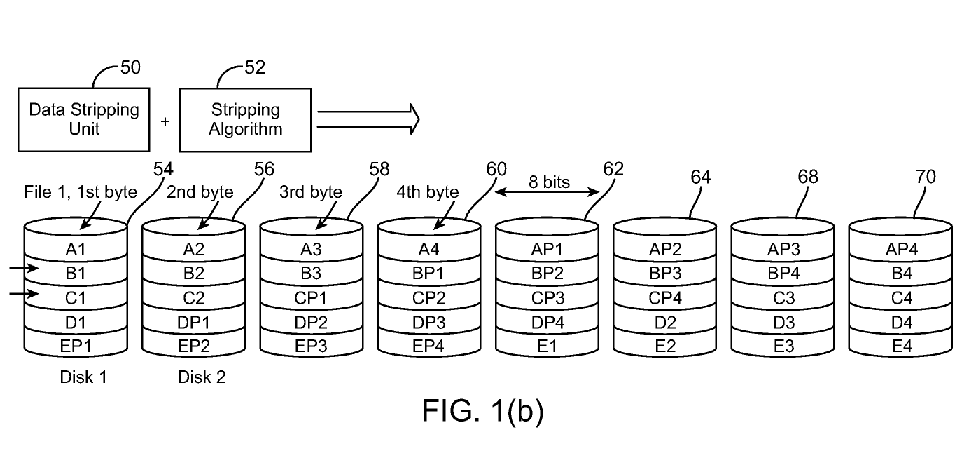

Referring now to FIG. 1(a), an electronic data storage device 10 is shown coupled to a host device 12, in accordance with an embodiment of the present invention. The host device 12 may be a host computer, a digital camera, etc. The storage device 10 is primarily for storing information and communicates with the host device 12 for transfer of information therebetween. Information includes data files examples of which include picture file and text file.

In one embodiment of the present invention, the electronic data storage device 10 is a flash memory storage solid state disk (SSD) comprising a number of disks. The total storage capacity of the SSD is approximately the sum of storage capacities of the disks. To ensure data correctness by fault-tolerant feature, overhead is included as parity bytes. An example of the electronic data storage device 10 is the redundant array of independent disks (RAID).

Flash, which is one type of non-volatile memory, is known, at times, to have bit errors according to manufacturing defect(s) or repeated write/read/erase operation. Error correction coding (ECC) methods and techniques are commonly employed in flash applications. However, increased defect bits, in page access operations, require powerful ECC methods. An embodiment of the present invention addresses such a need and provides an effective and cost sensitive solution thereof.

The flash memory storage SSD 10 includes an interface circuit 13, a solid disk array (SDA) controller 14, storage disks 26-32 and RS parity storage disks 36-46, in accordance with an embodiment of the present invention. The number of storage disks is N−4 where N might be as high as 255. In FIG. 1(a) only four storage disks 26-32 are indicated to demonstrate the basic idea. However, the RS parity storage disks 36-46 are limited to four as indicated. The SD array controller 14 includes a data stripping unit 24, a disk command register 16, an RS calculation unit 21 and a buffer 20, in accordance with an embodiment of the present invention.

The interface circuitry 13 is coupled to the host device 12 and to the data stripping unit 24, disk command register 22 and the central controller 16. The data stripping unit 24 is coupled to the disk command register 22 and the central controller 16 and the storage disks 26-32. The disk command register 22 is coupled to the data stripping unit 24 and central controller 16 which is coupled to the buffer 20 and the RS calculation unit 21. The RS calculation unit 21 is coupled to the RS parity storage disks 36-46.

Data stripping unit 24 divides the data and overhead, which is then distributed between various storage disks 26-32 so that a data file may be spread between one or more of storage disks. However, the location of the bytes in each sector in which a data file is stored is the same. For example, a data file may be divided into four different bytes and each byte stored in the identical location in four different disks. Spreading of data and overhead enables the RS calculation unit 21 to perform parallel processing, which reduces the amount of delay. As in the last example, a single data file may be stored in four different sectors in a plurality of storage disks. The RS calculation unit 21 processes the whole file as a block length data without having to wait for processing one whole sector to be finished before moving to the next sector. Thus, the speed of error detection and correction is increased.

The RS algorithm stored in the controller 16 is used to perform encoding and decoding. The RS calculation unit 21 includes an RS decoder, which is a fixed block length decoder. The data stripping unit 24 divides the data and overhead sent by the host 12 to generate a block length data which is distributed between the storage disks 26-32. The RS calculation unit 21 includes an RS encoder, which generates RS parity bytes needed by the RS decoder to detect possible error generated in retrieving the data from the electronic storage device 10.

There are four storage disks dedicated to storing the RS parity bytes. The RS calculation unit 21 calculates the parity bytes which are stored in the RS parity storage disks 36-44. The RS parity storage disks 36-44 comprise the overhead in the total storage data array and there are N−4 storage disks (only four of which are shown in FIG. 1(a), 26-32, due to space limitation) where N may be as high as 255. Thus, as the number of storage disks increases the ratio of overhead to stored data reduces substantially. In another embodiment of the present invention there are more than four RS parity storage disks to correct more than two disk crashes.

The disk command register 22 operates to transfer host commands to the solid disk array controller 14. The information sent by the host 12 is stored temporarily in the buffer 20 while RS calculations are being performed.

Referring now to FIG. 1(b), an embodiment of the present invention is shown to include four storage disks or solid disk arrays (SDA), 54-60, for storing data and four RS parity disks 62-70 for storing overhead including the RS parity bytes. The embodiment of FIG. 1(b) is an example of the present invention where N=8.

The data stripping unit 50 by using the stripping algorithm 52 divides the information provided by the host 12 into one or more parts to generate a block length data. Each data part consists of data sent to a storage disk 54, 56, 58 or 60 to be distributed almost evenly between the aforementioned storage disks. The overhead part of the block length data consisting of overhead is sent to the RS parity disks 62-70 to be distributed almost evenly therebetween. Accordingly, the RS calculation unit 21 decodes various data parts in parallel without having to finish processing one disk before moving to the next one thereby reducing the delay time. For example, if approximately 0.2 milliseconds is required to read each sector, by parallel processing the embodiment of the present invention is almost 16 (2×8 for 2 errors and 8 disks) times faster than without data stripping.

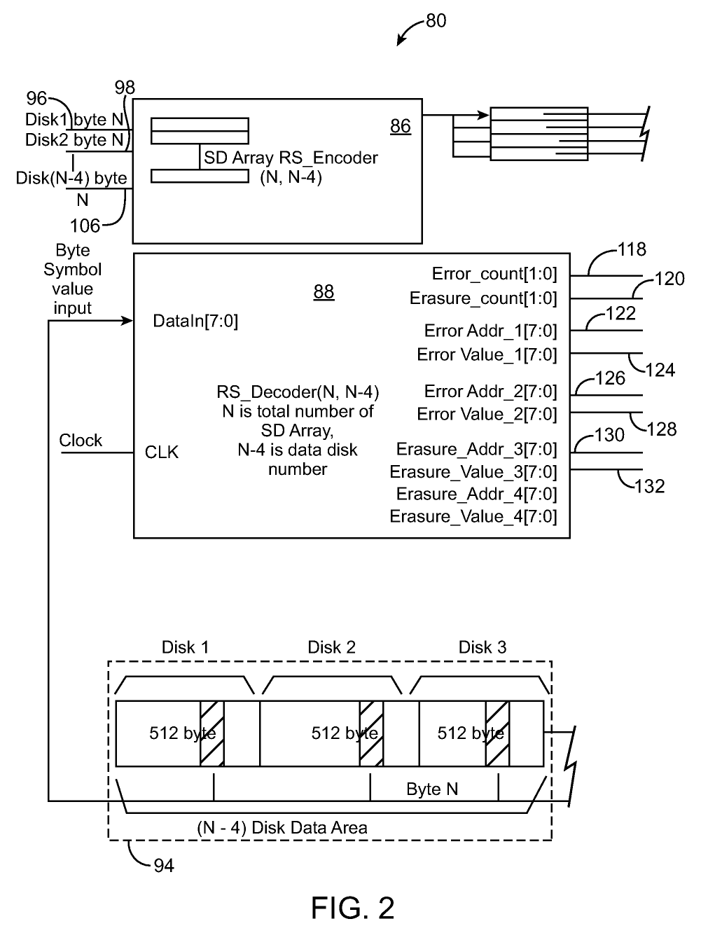

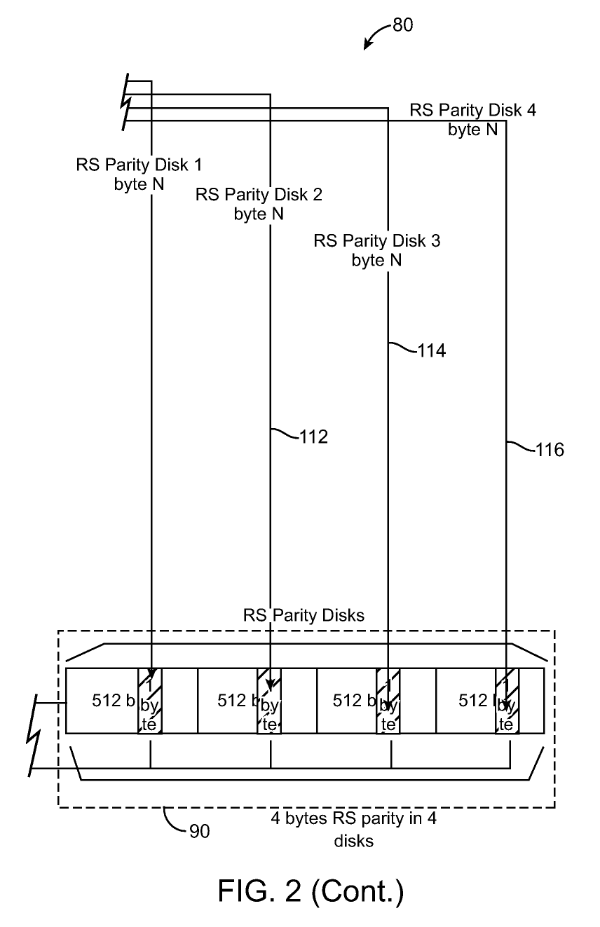

Referring now to FIG. 2, an RS calculation unit 21 is shown to include an RS encoder 86 and an RS decoder 88, in accordance with an embodiment of the present invention. Also shown in FIG. 2, are four RS parity disks 90 and N−4 storage disks 94.

The encoder 86 receives information provided by the host 12 in the form of bytes 96-106. Each sector within a disk comprises 512 bytes and the N^{th} byte for storage in disks 1 to N−4 as bytes 96-106, respectively. In the particular example shown in FIG. 2, N=7 thus there are three storage disks. The encoder 86 generates parity bytes the N^{th} of which are marked as 108-116 for storage in the four RS parity disks 90. In other words the four RS parity disks 90 each include sectors having 512 bytes the N^{th} byte thereof is marked as 108-116, respectively. The parity bytes are used for decoding to recover data in possible disk crashes in the electronic data storage device 10. Each of the solid state arrays or storage disks 94 has a local controller which decodes the data stored in the storage disk to detect and recover possible errors (or soft errors) therein.

The decoder 88 receives the data stored in the storage disks 94 for processing thereof to identify the magnitude and address of the disk crash or erasure. Specifically, output signals 118 and 120 indicate the number of errors and disk crashes or erasures, respectively. Output signals 112 and 126 indicate the location of the possible first and second errors, respectively, and signals 124 and 128 indicate the magnitudes or values of the first and second errors, respectively. Output signal 130 indicates the disk crash (or erasure) address and signal 132 indicates the value of erasure.

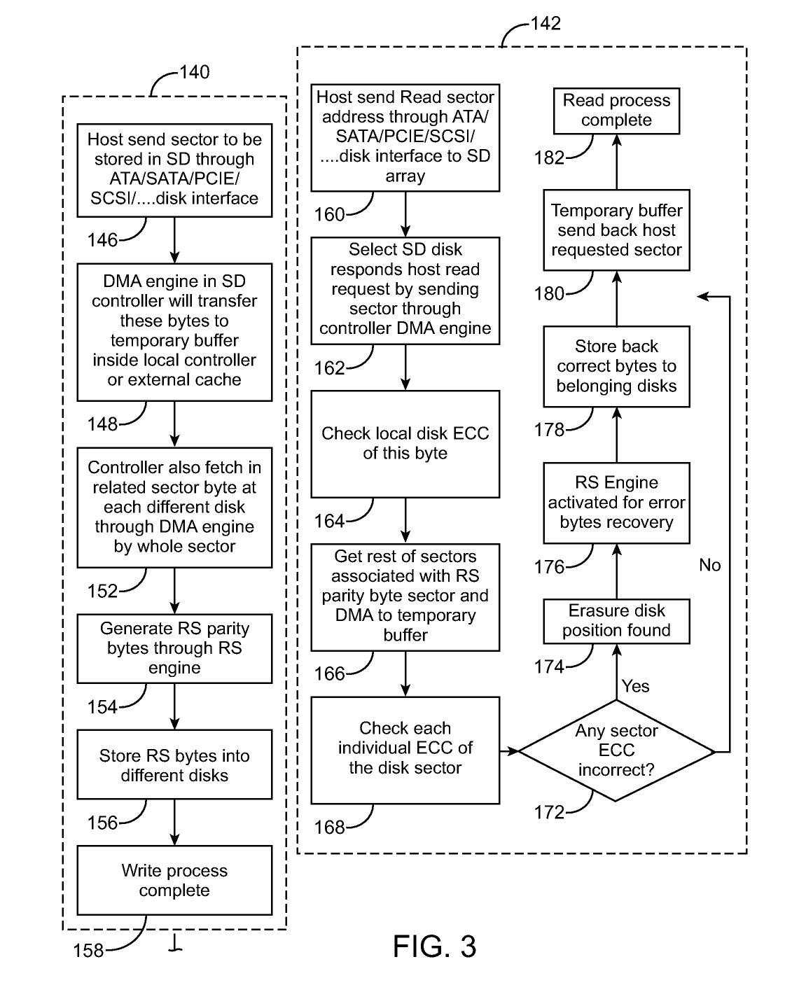

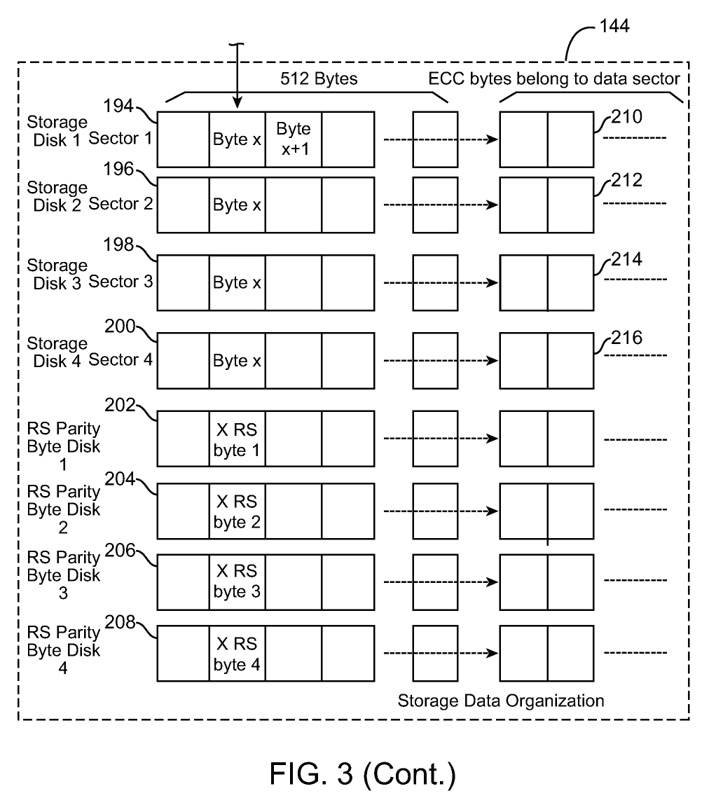

Referring now to FIG. 3, two flowcharts 140 and 142 for write and read processes, respectively, for an electronic data storage device are shown, in accordance with an embodiment of the present invention. Also shown in FIG. 3 is a schematic 144 of data storage organization in the electronic data storage device. In one embodiment of the present invention the electronic data storage device is a flash solid state disk (SSD) which includes one or more solid state arrays.

At the step 146 of the write process flowchart 140, the host 12 sends information to be stored in the storage disks through the interface circuitry 13. The central controller 16 has a direct memory access (DMA) engine which transfers the information bytes to the buffer 20 or to the local controllers in each of the solid disk arrays 54-60, as indicated at step 148.

For the purpose of encoding, the information provided by the host is processed by the data stripping unit 24 to generate the block length data. As a sector of the block length data is updated by writing new information, the remaining related sectors of the block length data need to be updated. At step 152, central controller 16 fetches the related sector bytes located at different storage disks through the DMA engine by whole sectors. At step 154, the RS calculation unit 21 generates parity bytes which are stored into different RS parity disks 62-70 at step 156. The whole process is thereby completed at step 158.

At step 160 of the read process flowchart 142, the host 12 sends new read sector address through the interface circuitry 13 to the flash solid state disk (SSD) 10. The storage disk having the appropriate sector determined by the address responds to the host read request by sending the sector to the DMA engine at step 162.

Step 164 indicates the activity of the local controller checking the overhead bytes, also known as error correction coding (ECC) bytes, in the storage disk for possible errors in reading the bytes. This is possible since each storage disk has an RS encoder/decoder whereby error detection and recovery is performed. At step 166 the relate sectors which comprise the block length data are fetched by the DMA engine and stored in a temporary buffer. In addition, the RS parity bytes associated with the block length data and stored in the RS parity storage disks are fetched by the DMA engine and stored in a temporary buffer. At step 168 the ECC bytes of the related sectors are checked for possible errors in reading the sectors.

At step 172 it is checked whether the ECC bytes indicate any errors in reading the data. The errors are indicated when the outcome of the RS decoding process is not compatible with the data. If the RS algorithm can correct possible errors in reading the data then no error is generated indicating the disk has not crashed and the data stored therein is correct. The block length data in the temporary buffers is sent back to the host at step 180 thereby completing the read process at step 182.

However, the case wherein the RS algorithm detects error and cannot recover the data is reported to the host as a disk crash or erasure. At step 174, the host is notified that the disk has failed which is reported back to the central controller 16 as a disk crash with a known position. As a result, the RS calculation unit 21 does not perform any error detection and recovery on the crashed disk. This case is referred to as erasure error. Instead, at step 176 the RS calculation unit 21 recovers the lost bytes due to erasure error and subsequently at step 178 the correct bytes are restored to the storage disks previously identified as crashed disks and stored in temporary buffers. The block length data in the temporary buffers is sent back to the host at step 180 thereby completing the read process at step 182.

The schematic 144 of data storage organization includes four storage disks 194-200, each of which has 512 bytes of data and associated ECC bytes 210-216, respectively. Also included are four RS parity storage disks 202-208. Also shown in the schematic 144 is a block length data written to four different sectors of the four storage disks 194-200. The block length data divided by the data stripping unit 24 is stored in byte x of each of the disks 194-200. Thus, the block length data is stored in the bytes with the same location in different storage disks 194-200. Similarly, the RS parity bytes are stored in the same relative location, i.e. byte x, of the four RS parity storage disks 202-208.

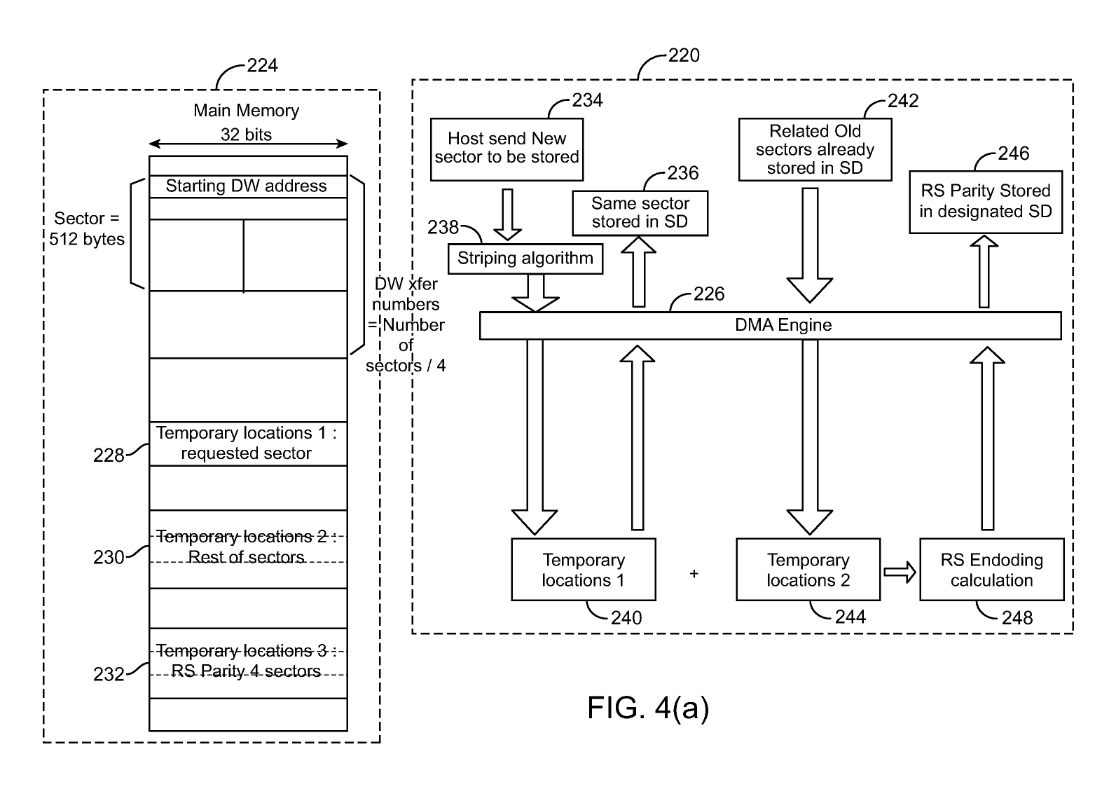

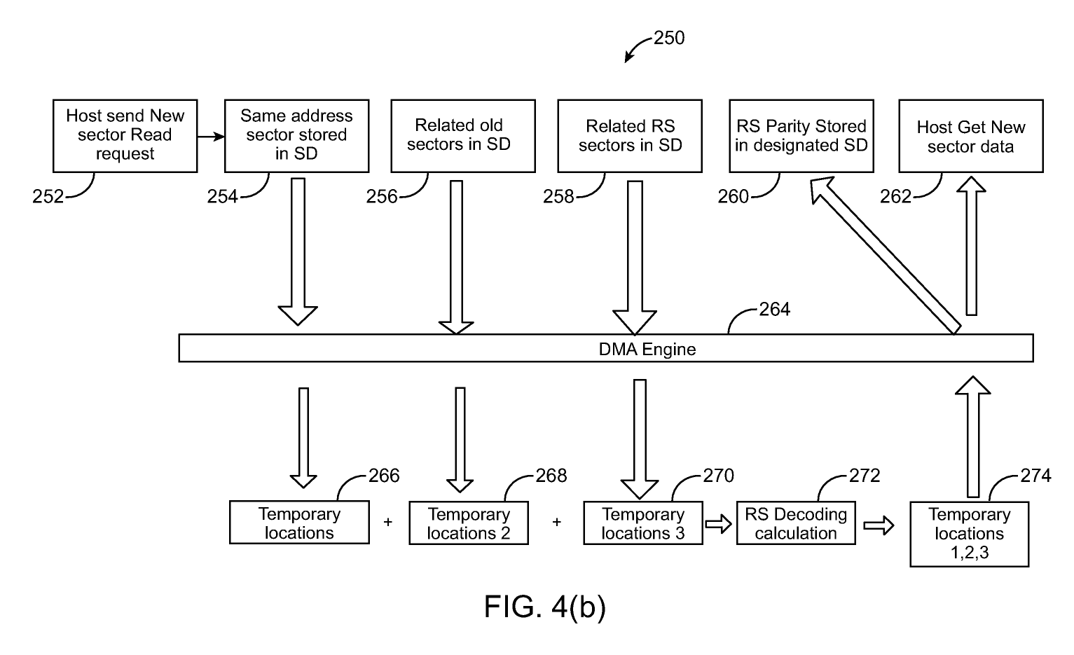

Referring now to FIG. 4(a), a block diagram 220 of an RS encoder in a write process and a main memory 224 are shown, in accordance with an embodiment of the present invention. The main memory 224 is located in the host. The sector to be written into the flash SSD is stored in the temporary location 228. Related thereto are other sectors comprising the block length data as determined by the data stripping unit 24. The related sectors are stored in the temporary location 230. The associated RS parity bytes are stored in the temporary location 232.

The RS encoder block diagram 220 indicates the DMA engine 226 which is included in the central controller 16. At step 234, the host 12 sends in new sector to be stored in the flash SSD 10 through the interface circuitry 13. In other embodiments of the present invention the host 12 sends one or more sectors for storage in the flash SSD 10. At step 238, the stripping algorithm is used to identify the related sectors which together with the new sector comprise the block length data. The new sector is stored in the storage disk determined by the data stripping unit 24 at step 236 through the DMA engine 226. The new sector is also stored in the temporary location 240 which is the same as temporary location 228 in the host.

At step 242 the related sectors included in the block length data are read and stored in the temporary location at step 244 through the DMA engine 226. The temporary locations 240 and 244 are combined at step 248 to perform RS encoding calculations, as described hereinabove in relation to FIG. 2. The RS parity bytes generated by the RS encoder are stored in designated RS parity storage disks at step 246.

Referring now to FIG. 4(b), a block diagram of an RS decoder 250 in the read direction is shown, in accordance with an embodiment of the present invention. At step 252 host 12 send in new sector read request for reading a new sector. In other embodiments of the present invention the read request is for one or more sectors to be read. At step 254 the new sector with the specified address is found in the appropriate storage disk and fetched through a first pipeline by the DMA engine 264. Therefrom the new sector is sent to the first temporary location for storage as indicated at step 266. The related sectors that comprise the block length data and are stored in other storage disks are fetched at step 256 through a second pipeline and sent by the DMA engine 264. The related sectors are then transferred to a second temporary location for storage at step 268. However, if the block length data includes only one sector then there are no related sectors to be read.

The related RS parity bytes are fetched from the RS parity storage disks at step 258 and sent trough a third pipeline to a third temporary location at step 270. The data and overhead in the first, second and third temporary locations are combined for RS decoding calculations to be performed thereon at step 272. The output of the RS decoding calculations is stored in a fourth temporary location at step 274. The DMA engine 264 sends the data stored in the fourth temporary location to the host 12 as the new sector data at step 262. The RS parity bytes stored in the fourth temporary location are sent to the RS parity storage disks for storage at step 260.

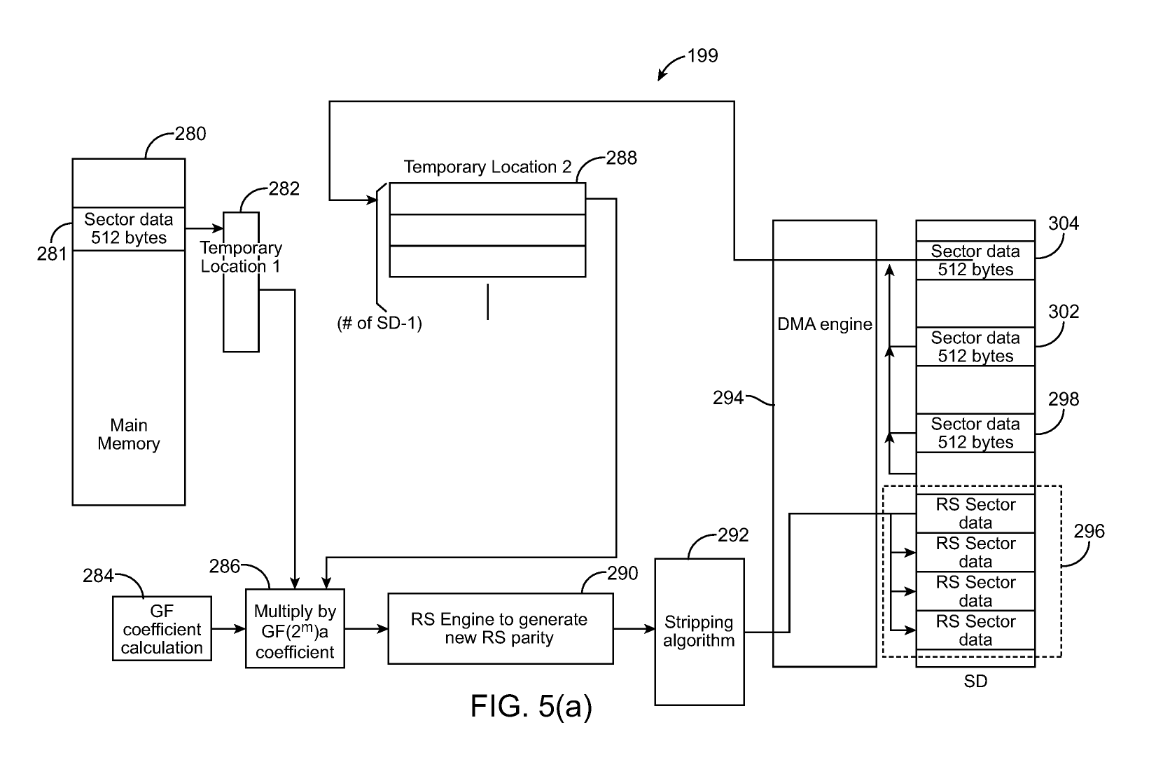

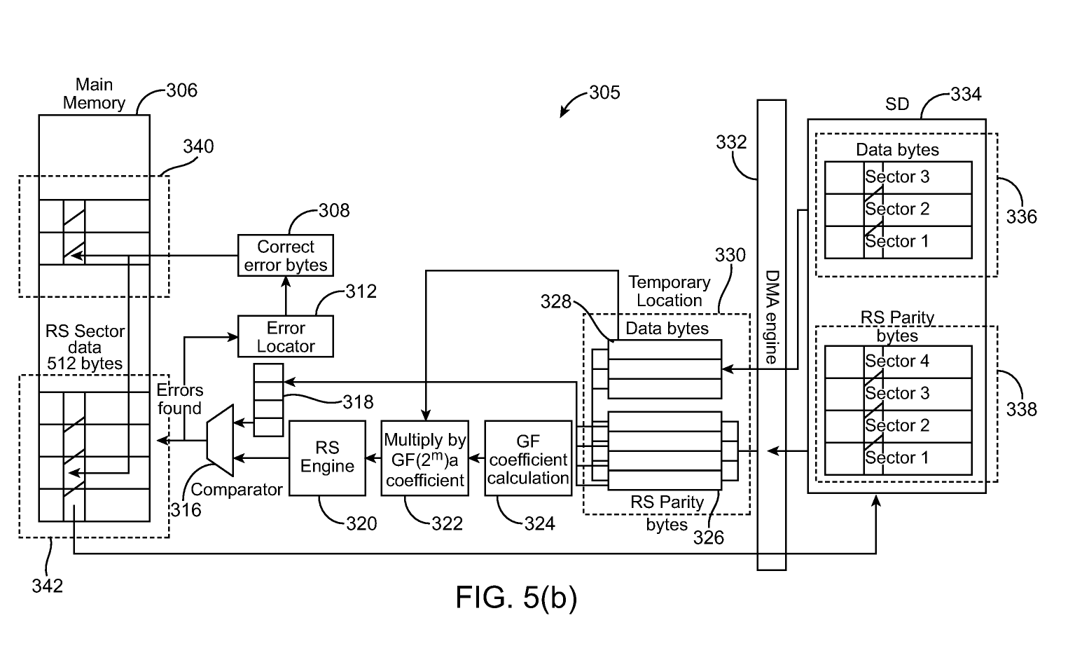

Referring now to FIG. 5(a), a write operation block diagram 199 is shown, in accordance with an embodiment of the present invention. Shown in the block diagram 199 is a data sector 281 to be written to the flash SSD 10 and included in the main memory 280 as a new write sector. The main memory 280 is generally located in the host 12. The sector 281 is sent to the temporary location at step p282 and stored therein as a new write sector. At step 284 Galois Field (GF) (2⁸) coefficients are calculated representing 8 bit symbols, as described hereinbelow. The GF (2⁸) are multiplied by the new write sector at step 286.

The related data sector bytes and the new write sector bytes, comprising the block length data, are fetched by the DMA engine 294 from the storage disk 295 and stored in the second temporary location at step 288. The related data sector bytes are also multiplied by the GF(2⁸) coefficients at step 286. The output of multiplications at step 286 is a message polynomial which is processed by the RS encoder at step 290 to generate RS parity bytes as described hereinbelow. The stripping algorithm is employed at step 292 to divide the message polynomial and parity bytes into parts to generate the block length data. Each part of the block length data is transferred to the storage disk 295 through the DMA engine 294. Included in the solid storage disks are data sectors 298-304 located within data storage disks for storing data portion of the block length data. Also in the storage disk 295 are RS sectors 296 located within the RS parity storage disks for storing RS parity bytes of the block length data.

Referring now to FIG. 5(b) a read operation block diagram 305 is shown, in accordance with an embodiment of the present invention. In the solid storage disk (SSD) 334 are three storage disks including data sectors 336 to be read by the host 12 and stored in the main memory 306 thereof. Also included in the SSD 334 are four RS parity disks including four sectors 338 for storing RS parity bytes used by the RS decoder for ECC.

Following transfer of a new sector read request from the host 12 to the flash SSD 10, the DMA engine 332 transfers new data bytes located in the data sectors 336 to the temporary data sectors 328 at step 330. The related RS parity bytes stored in the RS parity storage disks 338 are transferred by the DMA engine 332 to the temporary RS parity sectors 328 at step 330. The related RS parity bytes are transferred to a new temporary location at step 318.

At step 324 GF(2⁸) coefficients are calculated and at step 322 the data bytes are multiplied by the GF(2⁸) coefficients to generate a message polynomial. The message polynomial is processed by the RS engine at step 320 to generate calculated RS parity bytes. The calculated RS parity bytes are compared with the RS parity bytes at step 316. If the two RS parity bytes are identical no error is detected in the parity bytes and the data bytes are transferred to the main memory 306 at step 342. However, if the calculated RS parity bytes and the RS parity bytes associated with the data bytes do not match one or more errors are detected at step 312. The errors are corrected at step 308 to generate corrected data which is transferred to the main memory 306 at step 340.

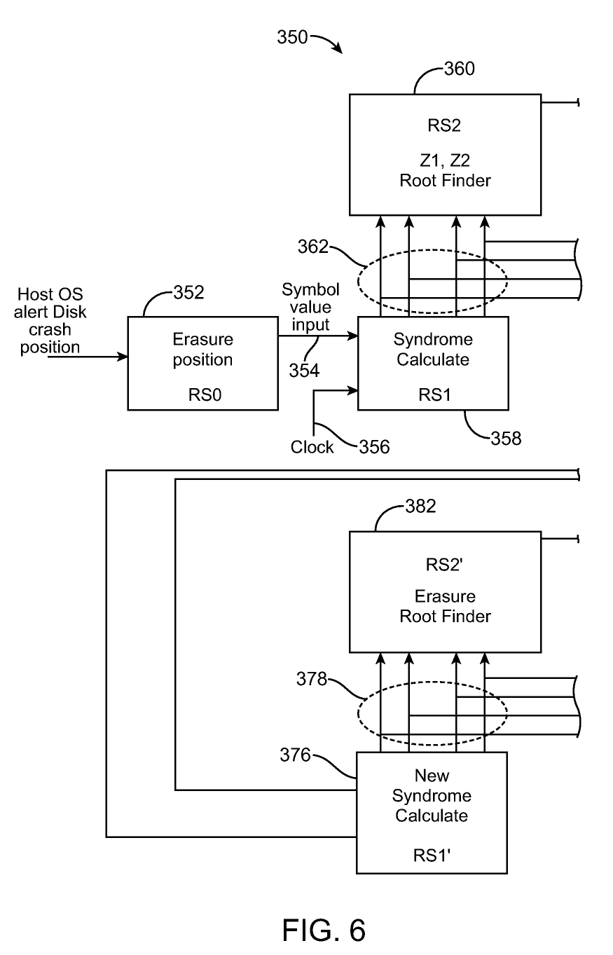

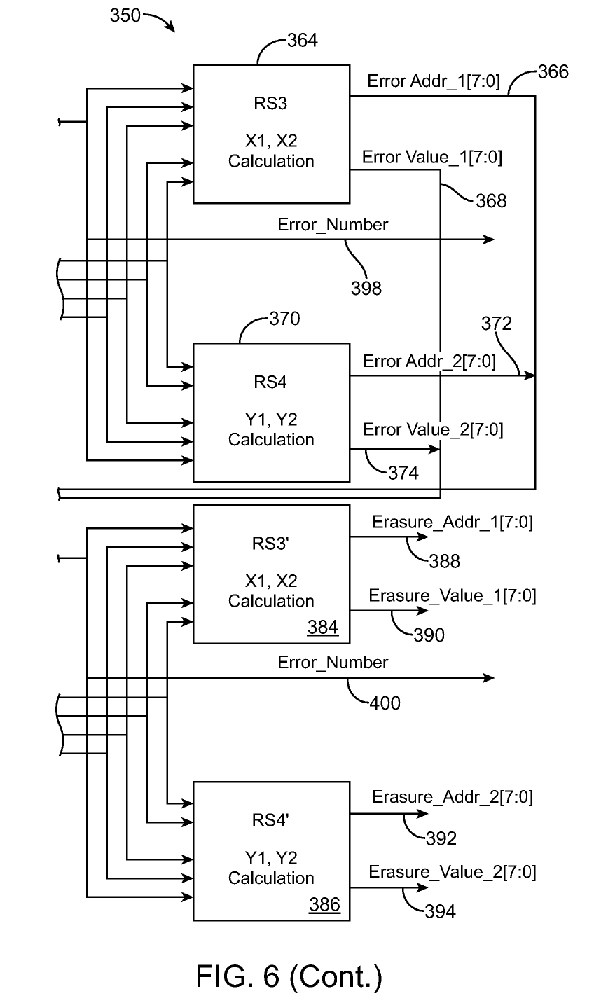

Referring now to FIG. 6, the RS decoder 350 is shown to include an erasure block 352, a syndrome calculate block 358, a root polynomial calculator 364, an error value calculator block 370, an error syndrome calculator block 376, an erasure root finder block 382, an erasure polynomial block 384 and an erasure error calculator block 386, in accordance with an embodiment of the present invention.

The erasure position block 352 receives input from the host operating system indicating the disk crash position and is operative to generate a symbol value input signal 354 which is sent to the syndrome calculate block 358. The syndrome calculate block 358 receives a clock signal 356 and is operative to generate and couple a calculated syndrome onto the syndrome signals 362 which are received by the blocks 360, 364 and 370. Further shown in FIG. 6 is the output of the block 360 serving as input to the blocks 364 and 370.

In FIG. 6, the block 358 is shown to generate an error number (Error_Number) 398 and the block 364 is shown to generate a first error address signal (Error Addr_1) 366 and the block 370 is shown to generate a second error address signal (Error Addr_2) 372. Moreover, a first error value signal (Error Value_1) 368 is shown generated by the block 364 and a second error value signal (Error Value_2) 374 is shown generated by the block 370. The block 364 calculates X1 and X2 and the block 370 calculates Y1 and Y2 in accordance with the equations presented hereinbelow.

The error address signals 366 and 372 and the error value signals 368 and 374 serve as inputs to the erasure syndrome calculate block 376.

The erasure syndrome calculate block 376 operates to generate and couple a calculated erasure syndrome onto the erasure syndromes 378 which are received by the block 382, 384 and 386. The erasure syndrome calculate block 376 generates an error number signal (Error_Number) 400. The block 384 generates a first erasure error address signal (Erasure_Addr_1) 388 and the block 386 generates a second erasure error address signal (Erasure_Addr_2) 392. Moreover, a first erasure error value signal (Erasure_Value_1) 390 is generated by the block 384 and a second erasure error value signal (Erasure_Value_2) 394 is generated by the block 386. The block 386 calculates Y1 and Y2, in accordance with equations presented hereinbelow.

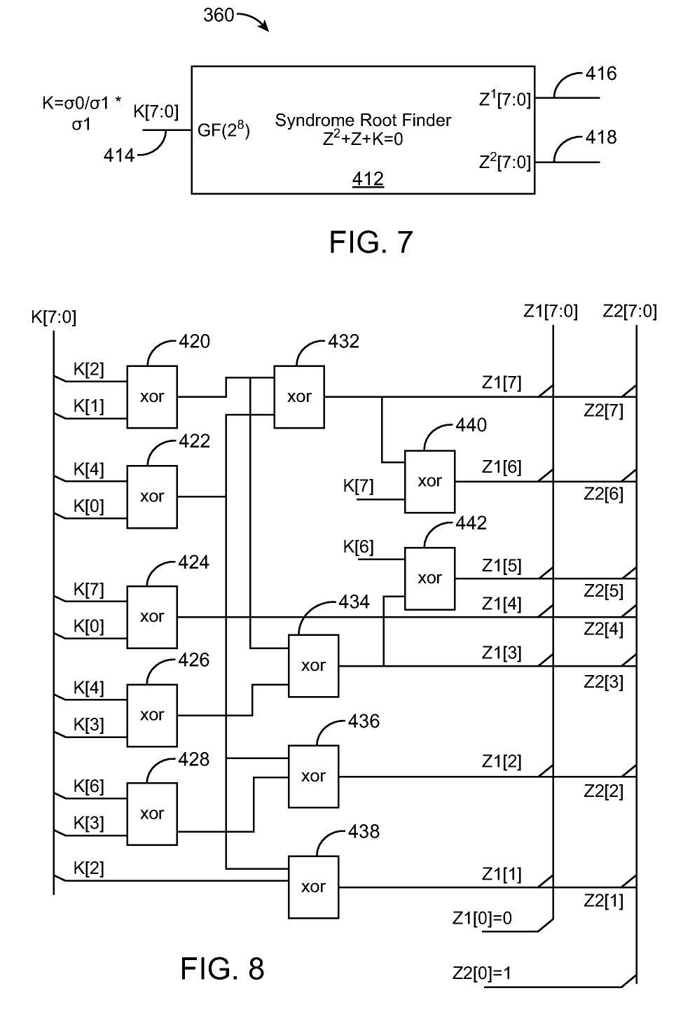

Referring now to FIG. 7, an exemplary embodiment of the block 360 is shown, in accordance with an embodiment of the present invention, wherein a syndrome root finder block 412 is shown to receive a syndrome K, of 8 bits, on the syndrome signal 414 provided by the block 358 of FIG. 6 and is further shown to generate two roots Z¹, generated onto the Z¹ signal 416 and Z² generated onto the Z² signal 418. Each of the roots Z¹ and Z² are shown to be 8 bits, as denoted by Z¹[7:0] and Z²[7:0], respectively, and the syndrome K is shown to be 8 bits, as denoted by K[7:0] with the notation “[X:0]” generally being X+1 in size, in accordance with an embodiment of the present invention. The signals 416 and 418 are each provided to the block 364. The example of FIG. 7 is carried through to subsequent figures to provide better understanding of additional details of the block of FIG. 6. In relation therewith, equations are presented below in a manner consistent with the figures. In one embodiment of the present invention, the block 412 causes the following equation to be implemented:

Z²+Z+K=0 Eq. (0)

FIG. 8 shows further details of the block 412 of the example of FIG. 7, in accordance with an embodiment of the present invention. The block 412 is shown to include Exclusive OR function (XOR) blocks 60-90 for generating the two roots Z¹ and Z² onto the signals 416 and 418, respectively. The syndrome K[7:0] is received as previously noted and each of its bits are ‘XOR’ed or compared to each other, in stages, in the manner shown in FIG. 8. For example, in the first stage of XORs, bits K[2] or the third bit of K are shown XORed with K[1] or the second bit of K. K[4] is shown XORed with K[0] and so on. The first stage of XORs is shown to incluse the XORs 420-428, the second stage of XORs is shown to include XORs 434-438, the third stage is shown to include XORs 440 and 442 and so forth. In a second stage of comparison, the outputs of some of the first stage of XORs are shown XORed to each other, in a manner consistent with that shown in FIG. 8. Some XORs beyond the first stage also compare a bit from K to the output of another XOR, for example, the XOR 440 is shown to compare the output of the XOR 432 to K[7] or the eight bit of K. Block 412 of FIG. 7 causes implementation of Eq. (0) and is an exemplary calculation of a Galois Field (2⁸).

In the interest of further clarification, an example of error count using block 412 is now presented. The example is to be used for flash or non-volatile memory error recovery and in the case where a page is 528 bytes in length. A page is 512 bytes of data and 16 bytes of spare or overhead which are used for RS encoding/decoding or ECC. Each page is divided or organized into three sections.

Also it is assumed two error counts format Reed Solomon code (RS) based on Galois Field GF(2⁸), where each symbol size is 8 and it is easier to adapt byte indications. RS(N, N−4) which N is code length, and 4<N≦255, N−4 is the length of message unit and it is the read out code in data area of flash memory, 4 bytes is the parity bytes generated from RS encoder for four crash disks or to correct two error sector with disk array. The data reside in sector (page) areas of SD array as long as

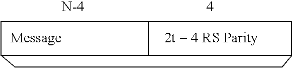

N: total Storage Data Array size 2s+r<=2t where s denotes error bytes and r denotes disk crash (Erasure) cases.

2(error byte)+(Erasure disk)≦2t. In the simple example, N=8 disks, and message bytes can be 4 bytes, 2t=4; total error bytes may be 2 bytes, however if only there is one byte of error, and two more disk crashes (erasure case), the RS encoder/decoder is still capable of detecting and correcting errors.

It is assumed r(x) is the receiving polynomial wherein errors might have occurred along with possible disk crashes.

Let rₛᵤₚ(x) denote the polynomial that suppress those disk crash bytes,
c(x) be the correct (golden) code word polynomial,
e(x) be error polynomial,

then r(x)=c(x)+e(x) Eq. (1)

Since two error bytes are assumed to be correctable by the RS encode/decoder and erasure crash disk cases are also allowed, four syndromes Sᵢ (i=0, 1, 2, 3) are needed for error byte location as well as erasure bytes value recovery. It is assumed two error positions are i₁, i₂; error symbol correct values are Y₁, Y₂;

Sᵢ=Y₁*X₁^{j}+Y₂*X₂^{j}; Eq. (2)

In Eq. (2), X₁=αⁱ^{₁}, X₂=αⁱ^{₂}; and X₁ and X₂ are error byte locations.

β₁=αⁱ^{₁}, β₂αⁱ^{₂}, β₃=αⁱ^{₃}, β₄=αⁱ^{₄}; where βᵢ is pre-known erasure disk crash locations and four erasure correct values are U₁, U₂, U₃, U₄.

σ(x)=(x−X₁)*(x−X₂)=x²+σ₁x+σ₀; Eq. (3)

σ(x) is error location polynomial, and σ₁ and σ₀ are two error locations. From Eq. (3) it follows that

σ₁=X₁+X₂, σ₀=X₁*X₂. Eq. (4)

Let

r(x)=X^{2t}*(a₀+a₁x+a₂x²+ . . . +aₖ₋₂x^{k-2}+aₖ₋₁x^{k-1})+(b₂ₜ₋₁X^{2t-1}+b₂ₜ₋₂x^{2t-2}+ . . . +b₁+b₀); (4A);

where r(x) is the receiving polynomial, and each coefficient aⱼ is associated with disk position X^{j}. t is number of error bytes that may be recovered. In this example t=2 but t may be any number. Also (a₀+a₁x+a₂x²+ . . . ) is the receiving data polynomial or M(x) obtained by reading each byte from different SD Array, Xⁱ is the disk position; (b₂ₜ₋₁ X^{2t-1}+b₂ₜ₋₂ x^{2t-2}+ . . . +b₁+b₀) is the RS parity bytes stored in the SD Array, which is generated from the remainder when x^{2t}*M(x) is divided by

$$\begin{matrix}g ( x ) = ( x - {α}^{0} ) ( x - {α}^{1} ) ( x - {α}^{2} ) ( x - {α}^{3} ) \\ = {x}^{4} + {α}^{2} {x}^{3} + {α}^{5} {x}^{2} + {α}^{5} x + {α}^{6} ;\end{matrix} \qquad Eq . ( 4 B )$$

The crash disk positions are first found out and then the corresponding terms in Eq. (4A) are zeroed out since the coefficients associated are no longer valid. As an example, r(x)=α⁶+α⁵x+α⁶x²+αx³, if f₂ is the only crash disk and is reported by the Host operating system (OS) probing before accessing required data, then rₛᵤₚ(x)=α⁶+α⁵x+0+αx³;

Next, Γ(X)=(1−α_{Zi} X)*(1−α_{Zj} X) is considered where Γ(X) is the erasure (crash disk) locator polynomial. In the above example Γ(X)=(1−α²X); since f₂ disk is crashed. Following is Modified Syndrome equations S(x): S(x)=[Γ(X)*rₛᵤₚ(X)] mod x^{2t}; where 2t=4 and rₛᵤₚ(x) is the suppressed r(x) by setting the crash disk positions equal to zero as previous example.

$$\begin{matrix}\begin{matrix}{S}_{0} ( {α}^{0} ) = {Y}_{1} * {X}_{1}^{0} + {Y}_{2} * {X}_{2}^{0} \\ = {Y}_{1} + {Y}_{2} ;\end{matrix} & Eq . ( 5 ) \\ \begin{matrix}{S}_{1} ( {α}^{1} ) = {Y}_{1} * {X}_{1}^{1} + {Y}_{2} * {X}_{2}^{1} \\ = {Y}_{1} * {X}_{1} + {Y}_{2} * {X}_{2} ;\end{matrix} & Eq . ( 6 )\end{matrix}$$

$$\begin{matrix}\begin{matrix}{S}_{2} ( {α}^{2} ) = {Y}_{1} * {X}_{1}^{2} + {Y}_{2} * {X}_{2}^{2} \\ = {S}_{1} * {σ}_{1} + {S}_{0} * {σ}_{0} ;\end{matrix} & Eq . ( 7 ) \\ \begin{matrix}{S}_{3} ( {α}^{3} ) = {Y}_{1} * {X}_{1} + {Y}_{2} * {X}_{2}^{3} \\ = {S}_{2} * {σ}_{1} + {S}_{1} * {σ}_{0} ;\end{matrix} & Eq . ( 8 )\end{matrix}$$

from above equations, σ₁ and σ₀ may be calculated as

σ₁=(S₁S₂+S₀S₃)/(S₁²+S₀S₂)=B/A=X₁+X₂; Eq. (9)

σ₀=(S₂²+S₁S₃)/(S₁²+S₀S₂)=C/A=X₁*X₂; Eq. (10)

and error values may be obtained by following terms:

Y₂=(S₀X₁+S₁)/σ₁; Eq. (11)

Y₁=S₀+Y₂; Eq. (12)

The terms A, B, C may be calculated in terms of Sᵢ to serve as error number indicator:

A=S₁²+S₀*S₂; Eq. (14)

B=S₁*S₂+S₀*S₃; Eq. (15)

C=S₂²+S₁*S₃; Eq. (16)

Now, a number of error and disk crash cases are considered.
(1) If no errors occurred and no disk crash reported by host OS, then

S₀=S₁=S₂=S₃=0; Eq. (13)

No recovery is needed as perfect case.
(2) No disk crash reported by the host operating system, A, B, C from Eqs. (14-16) are all non-zero values:
Two error bytes case with no disk crash needs to be recovered sine 2t=4 reaches the maximum correction amount. If two errors occur in read data, and assuming i₁, i₂ are the error locations then Y₁, Y₂ are two error symbol values.

$$\begin{matrix}\begin{matrix}{S}_{0} ( {α}^{0} ) = r ( {α}^{0} ) \\ = {Y}_{1} * {X}_{1}^{0} + {Y}_{2} * {X}_{2}^{0} \\ = {Y}_{1} + {Y}_{2} \_\end{matrix} & Eq . ( 24 ) \\ \begin{matrix}{S}_{1} ( {α}^{1} ) = {Y}_{1} * {X}_{2}^{1} + {Y}_{2} * {X}_{2}^{1} \\ = {Y}_{1} * {X}_{1} + {Y}_{2} * {X}_{2} ;\end{matrix} & Eq . ( 25 ) \\ \begin{matrix}{S}_{2} ( {α}^{2} ) = {Y}_{1} * {X}_{2}^{2} + {Y}_{2} * {X}_{2}^{2} \\ = {S}_{1} * {σ}_{1} + {S}_{0} * {σ}_{0} ;\end{matrix} & Eq . ( 26 ) \\ \begin{matrix}{S}_{3} ( {α}^{3} ) = {Y}_{1} * {X}_{1}^{3} + {Y}_{2} * {X}_{2}^{3} \\ = {S}_{2} * {σ}_{1} + {S}_{1} * {σ}_{0} ;\end{matrix} & Eq . ( 27 ) \\ \begin{matrix}A = {S}_{1}^{2} + {S}_{0} {S}_{2} \\ = ( {X}_{1}^{2} + {X}_{2}^{2} ) Y 1 * Y 2 \neq 0\end{matrix} & Eq . ( 28 )\end{matrix}$$

A≠0 since arbitrary different numbers squared and added together must be greater than zero if X₁, X₂ are not zero and not identical (as indicated in Table 1);

B=S₁S₂+S₀S₃=(X₁+X₂)*(X₁²+X₂²)*Y₁*Y₂≠0; Eq. (29)

C=S₂²+S₁S₃=X₁*X₂*(X₁²+X₂²)*Y₁*Y₂≠0; Eq. (30)

Using cyclic characteristic of Galois Fields (GF), we may assume

Xᵢ=σ₁*Zᵢ; Eq. (31)

where i may be 1 or 2 in the example above.
In order to make σ(x)=x²+σ₁x+σ₁x+σ₀ simple, it is easier to consider

σ(z)=z²+z+K; Eq. (31A)

where K=σ₀/σ₁².
Once the root of above equation is found, we may recover X=σ₁*Z again.
It may be assumed x=σ₀*z also, however, no benefit results for doing so since it cannot simplify σ(x) equation.

Roots of σ(x) are error locations X₁, X₂, where the error symbol locations occur. Most of the RS decoding problem is centered around finding these two roots.

Now an easy way and simple hardware is introduced to find the roots. It is assumed Z₁, and Z₂ are roots of σ(z). Substituting Z₁, Z₂ into Eq (31A), it is found that

Z₁²+Z₁+K=0; Eq. (32)

Z₂²+Z₂+K=0; Eq. (33)

Subtraction of these two equations, results in

(Z₁²−Z₂²)+(Z₁−Z₂)=0, Eq. (34)

in Galois field operation “−” is identical with “+” so it is found that

(Z₁²+Z₂²)+(Z₁+Z₂)=0, Eq. (35)

Since 2*Z₁*Z₂=Z₁*Z₂+Z₁*Z₂=0; Eq. (36)

because two identical terms added together equal zero under Galois operation. It follows that

(Z₁²+Z₂²+2Z₁*Z₂)+(Z₁+Z₂)=0,

(Z₁+Z₂)²+(Z₁+Z₂)=0; Eq. (37)

(Z₁+Z₂)*(Z₁+Z₂+1)=0; Eq. (38)

which implies

Z₁+Z₂=0; or Z₁+Z₂+1=0; Eq. (39)

However Z₁=Z₂ is not possible, as two error locations should not be same, the only choice is

Z₁=Z₂+1; or Z₂=Z₁+1; or Z₁+Z₂=1; Eq. (40)

The above three equations are valid at the same time under Galois operation.

Also 1 in above equation means (1000 0000) if GF(2⁸), and Z₁ and Z₂ highest bit (bit position 0) should be toggled to each other.

Examples like
Z₁=0110 0110;
Z₂=1110 0110;
   where LSB bits toggled to each other are underlined according to above explanation.

Again Z₁²+Z₁+K=0;

Z₁*(Z₁+1)+K=0; Eq. (41)

Z₁*(Z₁+1)=K; Eq. (42)

It is assumed

Z₁=β₁*α+β₂*α²+β₃*α³+β₄*α⁴+β₅*α⁵+β₆*α⁶+β₇*α⁷; Eq. (43)

where βᵢ are coefficients of the above Z equation.

### Then

Z₁+1=1+β₁*α+β₂*α²+β₃*α³+β₄*α⁴+β₅*α⁵+β₆*α⁶+β₇*α⁷; Eq. (44)

βⱼ is 1 or 0 only in the above derivation, so equalities hold for βⱼ*βⱼ=βⱼ, βⱼ+βⱼ=0.
These Two terms may be swapped without influencing the final result,
Multiply two terms together in Eq. (42), it is found

(β₇*α¹⁴+β₆*α¹²+β₅*α¹⁰+β₄*α⁸)+β₇*α⁷+(β₆+β₃)*α⁶+β₅*α⁵+(β₄+β₂)*α⁴+β₃*α³+(β₂+β₁)*α²+β₁*α=K; Eq. (45)

where the fact that β₇*β₇=β₇ is used.
Also β₇*β₆+β₇*β₆=0; as same terms add together to yield zero in Galois Field (GF) operation.

If Galois Field GF(2⁸) is referenced it is found that

α¹⁴=(1100 1000)=1+α+α⁴;

α¹²=(1011 0011)=1+α²+α³+α⁶+α⁷;

a¹⁰=(0010 1110)=α²+α⁴+α⁵+α⁶;

α⁸=(1011 1000)=1+α²+α³+α⁴;

Substitute these four values into the above equation, it is found that

β₇+β₆=K₇; Eq. (46)

β₃+β₅=K₆; Eq. (47)

β₇+β₅+β₂=K₄; Eq. (48)

β₆+β₄+β₃=K₃; Eq. (49)

β₆+β₅+β₄+β₂+β₁=K₂; Eq. (50)

β₇+β₁=K₁; Eq. (51)

β₇+β₃+β₄=K₀; Eq. (52)

K=σ₀/σ₁²=K₇*+⁷+K₆*α⁶+K₅*α⁵+K₄*α⁴+K₃*α³+K₂*α²+K₁*α¹+K₀ Eq. (53)

Kⱼ (j=7 . . . 0) are coefficients of Eq (53) 8 bit symbol value, and K may be obtained from once Syndrome Sᵢ is calculated, and σ₀, σ₁ values are also calculated after Sᵢ is found;
Comparing Eq (46) and (52), it is found that

β₄=K₇+K₀; Eq. (54)

adding Eq (48), (50), and (51), and substituting β₄, all double terms are eliminated because of Galois “+” is actually exclusive OR function, it follows that

β₆=K₇+K₄+K₂+K₁+K₀; Eq. (55)

From Eq (46), it follows that

β₇=K₄+K₂+K₁+K₀; Eq. (56)

From Eq (51), it follows that

β₁=K₄+K₂+K₀; Eq. (57)

From Eq (49) and (52), it follows that

β₇+β₃=K₃+K₀; Eq. (58)

β₃=K₄+K₃+K₂+K₁; Eq. (59)

From Eq (47), it follows that

β₅=K₆+K₄+K₃+K₂+K₁; Eq. (60)

From Eq (48), it follows that

β₂=K₆+K₄+K₃+K₀; Eq. (61)

After all βⱼ (j=1 . . . 7) are found from four syndrome formulas, Z₁ is found from Eq (40), Z₂ may also be found by adding 1(1000 0000) to it.
X₁, X₂ values are recovered by using Eq (31),

X₁=σ₁*Z₁;

X₂=σ₁*Z₂;

Y₂=(S₀X₁+S₁)/σ₁; Eq. (11)

Y₁=S₀+Y₂; Eq. (12)

Above Y₁ and Y₂ are error symbol value, and

e(x)=X₁*Y₁+X₂*Y₂; Eq. (62)

Correct code word c(x) may be obtained from Eq (1) by adding r(x) and e(x), in two error byte case, since already maximum number of error recovery limit is rerached, no erasure case is allowed, r(x)=rₛᵤₚ(x) c(x)=r(x)+e(x) as shown in Eq. (1).
As described hereinabove explanation, error locations X₁, X₂ need only be calculated from Kⱼ, which in turn comes from syndrome value σ₀/σ₁² with very simple exclusive operations. It does not need either ROM expensive silicon area which is proportional to code size, or complex operations that requires lots of hardware for implementation.

It is noted that case (2) is a two error location case, so there is no room for disk crash recovery, since 2s=2t.

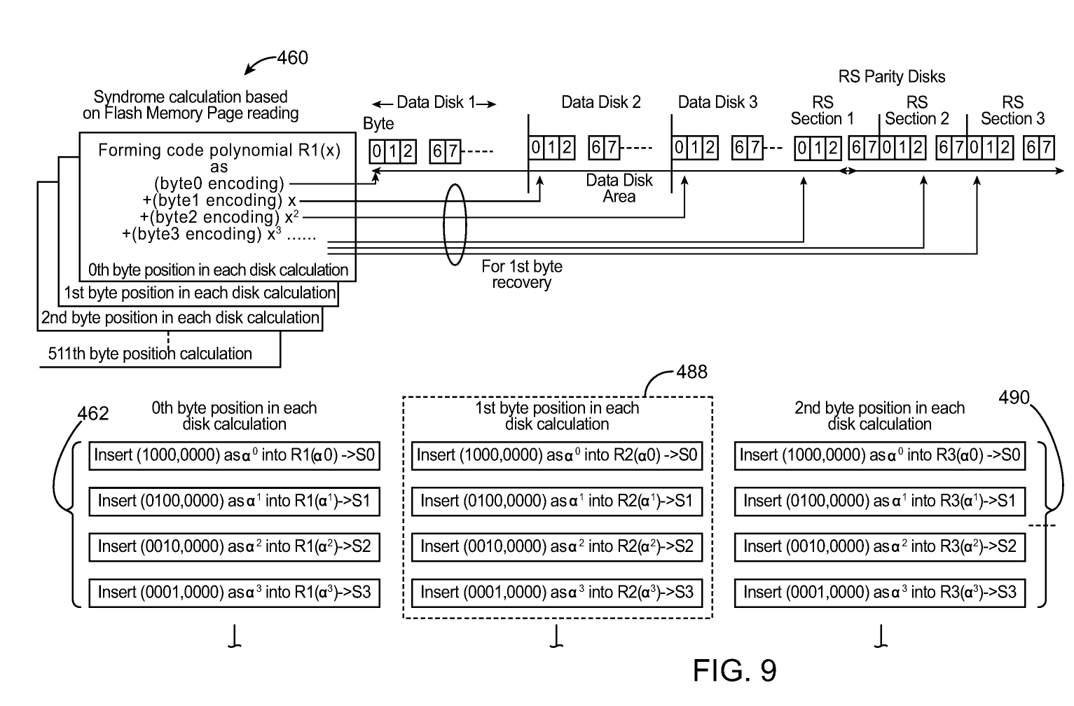

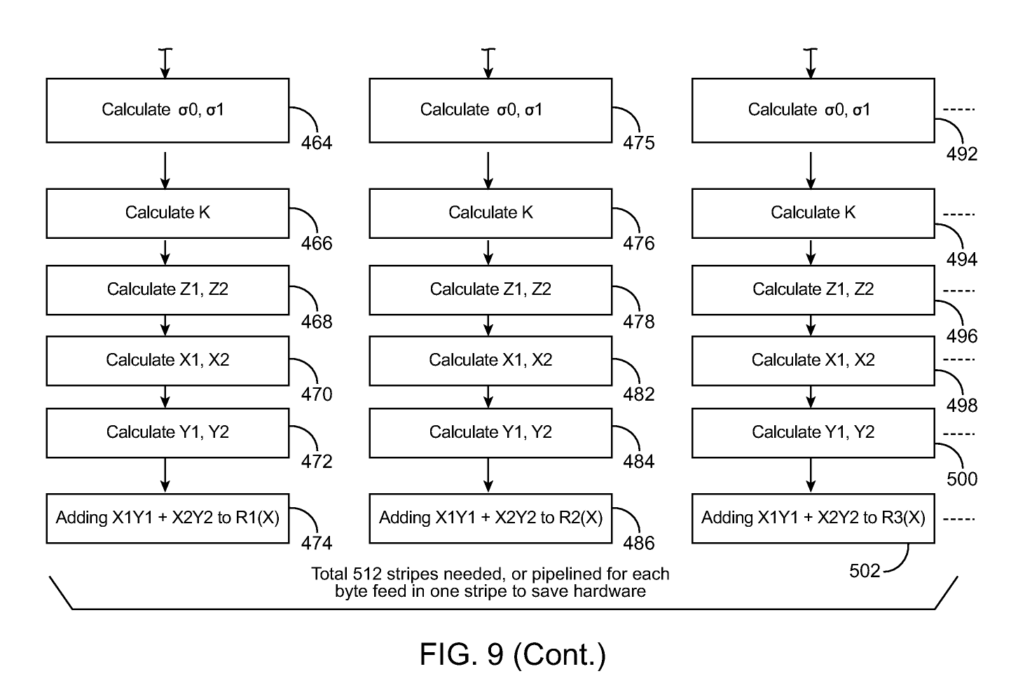

Exemplary implementation of the foregoing is shown relative to FIG. 9 wherein a flowchart of the steps performed in recovering data is shown, in accordance with one method of the present invention. At step 460, the syndrome is calculated based on a flash memory page that is read from flash memory to form the receiving polynomial R₁(x). As previously noted, a page is sectioned into three units or sections. Next, at step 462, the syndromes S₀-S₃ are calculated, for the first section of the page, by inserting the respective binary values, such as ‘1000,000’ for S₀ and the like as α into R₁(α). Similarly, S₀-S₃ for a second section of the page is calculated at step 488 and a S₀-S₃ for a third section of the page is calculated at step 490.

After step 462 σ₀ and σ₁ are calculated from the syndromes S₀-S₃, in accordance with the foregoing equations, for the first section, at step 464 and similarly at step 475, after the step 488, the σ₀ and σ₁ are calculated from the syndromes S₀-S₃, in accordance with the foregoing equations, for the second section and at step 492, after step 490, the σ₀ and σ₁ are calculated from the syndromes S₀-S₃, for the third section of the page.

After step 464, K is calculated at step 466 based on the foregoing equations, for the first section and after the step 475, K is calculated, at step 476, for the second section of the page and after the step 492, at step 494, K is calculated for the third section of the page.

After step 466, Z₁ and Z₂ are calculated for the first section of the page at step 114, based on the foregoing equations, for the first section and are used to calculate X₁ and X₂, at step 470 after which, at step 472, Y₁ and Y₂ are calculated, after which at step 474, X₁*Y₁ is added to X₂*Y₂ and the sum thereof is added to R₁(x). In this manner the first data segment is recovered. The notation “*” refers to the multiplication function or operator.

After step 476, Z1 and Z2 are calculated, for the second section of the page, at step 478, based on the foregoing equations, and used to calculate X1 and X2, at step 482 after which, at step 484, Y1 and Y2 are calculated, after which, at step 486, X1*Y1 is added to X2*Y2 and the sum thereof is added to R2(x). In this manner the second data segment is recovered.

After step 494, Z₁ and Z₂ are calculated for the third section of the page, at step 496, based on the foregoing equations, and are used to calculate X₁ and X₂, at step 498 after which, at step 500, Y₁ and Y₂ are calculated, after which, at step 502, X₁*Y₁ is added to X₂*Y₂ and the sum thereof is added to R₃(x). In this manner the third data segment is recovered.

(3) K=0 and Si≠0: One error byte case, and involving several different sub-cases.
(3A) Single error byte without any disk crashes.
(3B) Single error byte with one or two disk crash which might coexist together as worst case;
First, the error byte disk position is found, and the correct value for this byte is recovered according to description hereinbelow, then the crash disk correct byte value is found. It is noted that error byte position should not be overlapped with crash disk values, since crashed disk has all sector value wrong.
(3A) If only single error occurs (No erasure occurring), and assuming error location is i₁, error value is Y₁, since only one error value is associated with X₁,

S₀=Y₁≠0; Eq. (17)

S₁=Y₁*X₁≠0; Eq. (18)

S₂=Y₁*X₁²≠0; Eq. (19)

S₃=Y₁*X₁³≠0; Eq. (20)

All Sᵢ≠0 Does not imply two errors, but implies that at least one error occurs.

### But

Y₁=S₀; Eq. (17)

and simply changing sides of equation in equation (18) X₁=S₁/Y₁=S₁/S₀; it is found that

σ₁=(S₁*S₂+S₀*S₃)/(S₁²+S₀*S₂)=X₁³Y₁²+X₁³Y₁²=X₁+X₂=0; Eq. (21)

σ₀=(S₂²+S₁*S₃)/(S₁²+S₀*S₂)=X₁⁴Y₁²+X₁⁴Y₁²=X₁*X₂=0; Eq. (22)

A=X₁²Y₁²+X₁²Y₁²=0<=A; Eq. (23)

So σ₁=σ₀=0 with no erasure case implies only one error occurs, Table 1 explains σ₁=0 case.

Y₁=S₀;

X₁=S₁/Y₁; From Eq. (17-18)

(3B) Single error byte with one or two disk crashes which might coexist together as worst case:

The terms for r(x) zeroed out since failing disk value is not meaningful, then Eq (23G) is used to find out one error byte location and value, first temporary syndrome Sᵢ is calculated from rₛᵤₚ as seen from Eq (23AF-DF), then another syndrome formula is formed as Eq (23H) by combining Γ(x) and rₛᵤₚ₀(1), rᵣₛᵤₚ(α), rₛᵤₚ₂(α²) and rₛᵤₚ₃(α³), again this syndrome may be used to find out error byte position first. Details will be shown hereinbelow by way of an example. Once X₁, Y₁ is known,

r_{new sup}(x)=r_{Sup}+e(x)=r_{Sup}+X^{X1}*Y₁; Eq. (23A)

Whole error position polynomial is calculated as

Ψ(x)=Λ(x)*Γ(x)=(1−αⁱx)*(1−βⁱx)*(1−β^{j}x); Eq. (23B)

where Λ(x) is the error byte location polynomial (1−αⁱ x), and Γ(x) is the disk crash location polynomial (1−βⁱx)*(1−β^{j}x).
An erasure syndrome value may be found by

S(x)={Ψ(x)*[r_{newsup0}(1)+r_{newsup1}(α)x+r_{newsup2}(α²)x²+r_{newsup3}(α³)x³]} mod x⁴ (23C)

Using the four Sᵢ(1, α, α², α³), the disk crash value is found easily, but maximum disk crash number is limited to two. Now an example is considered.

### Example:

### Considering

c(x)=α⁴x⁶+α⁵x⁵+α²x⁴+α⁴x³+α²x²+α³x+α²; Eq. (23D)

where c(x) is the golden coding example in GF(2³) for RS(7,3) two error correction case for easier illustration. RS bytes in correct coding is a α⁴x³+α²x²+α³x+α² as RS parity symbols to correct two errors maximum, and (α²x⁴+α⁵x⁵+a⁴x⁶) is true data code for storage. Symbol size is 3 bit per symbol for easy demonstration. In this example, there are a total of seven disks, 3 disks are data storage disks, and 4 disks are for RS recovery, also known as RS parity disks. In real application, since GF(256) or GF(2⁸) approach is used, total disk size can be a maximum of 255 disks with only four disks for RS recovery purposes. The overhead is 1.57%, but correction capability is much better than current applications.

To verify the theory, if the four roots (1, α, α², α³) are inserted into c(x), they should be all zeroes.

C(1)=0; Eq. (23AD)

C(α)=0; Eq. (23BD)

C(α²)=0; Eq. (23CD)

C(α³)=0; Eq. (23DD)

However due to presence of disk fail, f₁ and f₆ are failing, which are x⁶ and x terms relating to Eq (23C) and two disk crashes happen during disk locations 1 and 6, which are a x and a⁴x⁶ and should be ignored. The SSD disk controller reads Eq (23D) as

r(x)=α⁴x⁶+α⁵x⁵+α²x⁴+x³+α²x²+α³x+α² Eq. (23E)

with x3 term italicized as error and two terms underlined due to disk crash.

### Then

rₛᵤₚ(x)=0+α⁵x⁵+α²x⁴+x³+α²x²+0+α² Eq. (23F)

is used to find temporary syndromes rᵢ, i ranging from 0 to 3

r_{sup 0}(1)=α; Eq. (23AF)

r_{sup 1}(α)=α⁵; Eq. (23BF)

r_{sup 2}(α²)=α⁶; Eq. (23CF)

r_{sup 3}(α³)=α⁴; Eq. (23DF)

Then syndrome equations are used for the first error byte location calculation,

Γ(x)=(x−βⁱ)*(x−β^{j})=(x+α)*(x+α⁶)=1+α⁵x+x²; Eq. (23G)

where i, j reflect 1 and 6 disk crash position inversion as disk 6 is α and disk 1 is α⁶. The syndrome S(x) is given as,

S(x)=[Γ(x)*(r₀+r₁x+r₂x²+r₃x³)] mod x⁴=[(1+α⁵x+x²)(α+α⁵x+α⁶x²+α⁴x³)] mod x⁴=α⁵x³+α²x²+αxαα; Eq. (23H)

S₀(1)=α⁵+α²+α+α=α³

S₁(α)=α

S₂(α²)=α⁴

S₃(α³)=α²

A=S₁²+S₀S₂=α²+1=α⁶

B=S₁S₂+S₀S₃=α⁵+α⁵=0

C=S₂²+S₁S₃=α+α³=1

σ₁=(S₁*S₂+S*S₃)/(S₁²+S₀*S)=B/A=X₁+X₂=0

σ₀=(S₂²+S₁*S₃)/(S₁²+S₀*S₂)=c/A=α

σ₁=0 implies this example is a single error case, because from below Table 1 only two identical roots can cause zero. Table 1 indicates addition of GF(8) combinations.

TABLE 1
Addition of all GF(8) combinations

| | | | | | | | | |
|---|---|---|---|---|---|---|---|---|
| + | 0 | 1 | α | α + 1 | α² | α² + 1 | α² + α | α² + α + 1 |
| 0 | 0 | 1 | α | α + 1 | α² | α² + 1 | α² + α | α² + α + 1 |
| 1 | 1 | 0 | α + 1 | α | α² + 1 | α² | α² + α + 1 | α² + α |
| α | α | α + 1 | 0 | 1 | α² + α | α² + α + 1 | α² | α² + 1 |
| α + 1 | α + 1 | α | 1 | 0 | α² + α + 1 | α² + α | α² + 1 | α² |
| α² | α² | α² + 1 | α² + α | α² + α + 1 | 0 | 1 | α | α + 1 |
| α² + 1 | α² + 1 | α² | α² + α + 1 | α² + α | 1 | 0 | α + 1 | α |
| α² + α | α² + α | α² + α + 1 | α² | α² + 1 | α | α + 1 | 0 | 1 |
| α² + α + 1 | α² + α + 1 | α² + α | α² + 1 | α² | α + 1 | α | 1 | 0 |

We know only one error occurs during receiving and
X₁=Sqrt of σ₀=α⁴, and it is X₁=X³ term Y₁=S₁/X₁=α/α³=α⁵,
   Correct value for c(x) x³ term (since X₁=α³ from above derivation) is α⁵+1=α⁴; where 1 is from original rₛᵤₚ(x) with one error, which may be seen from Eq (23E)

### Correct

$$\begin{matrix}{r}_{new sup} ( x ) = {α}^{2} + {α}^{2} {x}^{2} + ( 1 + \underline{{α}^{5} )} {x}^{3} + {α}^{2} {x}^{4} + {α}^{5} {x}^{5} \\ = {α}^{2} + {α}^{2} {x}^{2} + \underline{{α}^{4} {x}^{3}} + {α}^{2} {x}^{4} + {α}^{5} {x}^{5}\end{matrix} \qquad Eq . ( 23 I )$$

Then 1, α, α², α³ are inserted into above Eq (23I) to find the following 3^{rd} syndrome terms,

Λ(x)*Γ(x)*(s′₀+s′₁(α)x+s′₂(α²)x+s′₃(α³)x)mod x⁴=[(1−αⁱx)*(1−βⁱx)*(1−β^{j}x)*(s′₀+s′₁(α)x+s′₂(α²)x+s′₃(α³)x)] mod x⁴;

=[(1−α³x)(1−αx)(1−α⁶x)(α⁶+α⁶x+α³x²+α⁵x³)] mod x⁴

S′₁(x) is from Eq. (23I)

S′₀(1)=α⁶;

S′₁(α)=α⁶;

S′₂(α²)=α³;

S′₃(α³)=α⁵;

A′=S′₁²+S′₀S′₂=α³

B′=S′₁S′₂+S′₀S′₃=α

C′=S′₂²+S′₁S′₃=α³

σ₁=B′/A′=α⁵=X₁+X₂;

σ₀=c′/A′=1=X₁*X₂;

Once the two disk crash positions are substituted, the failing disk bytes are recovered easily as:

f₆=(S₀X₁+S₁)/σ₁=(α⁶*α+α⁶)/α⁶=(1+α⁶)/α⁵=α²/α⁵=α⁴;

f₁=S₀+Y₂=α³;

### Then

e(x)=α³x+α⁴x⁶; from above derivations since

r_{new sup}(x)=α²+α²x²+α⁴x³+α²x⁴+α⁵x⁵ Eq. (23I)

where α⁴x³ is the error byte term, and

$$\begin{matrix}c ( x ) = {r}_{new sup} ( x ) + e ( x ) \\ = \underline{{α}^{4} {x}^{6}} + {α}^{5} {x}^{5} + {α}^{2} {x}^{4} + {α}^{4} {x}^{3} + {α}^{2} {x}^{2} + \underline{{α}^{3} x} + {α}^{2} ;\end{matrix} \qquad Eq . ( 23 J )$$

Eq. (23J) is identical to Eq. (23D). In total three syndrome calculations are performed for the syndrome, temporary syndrome and erasure syndrome in the embodiment of the present invention described hereinabove.

Conventional calculations for erasure byte values of disk crash cases are given by:

$${f}_{i} = \frac{{α}^{i} * \{ ( 1 + 1 / {α}^{xi} ) * E ( 1 / {α}^{xi} ) \} mod {x}^{2 t}}{{Ψ}^{′} ( 1 / {α}^{xi} )} ;$$

where i is the fail disk number and Ψ′(x) is the differentiation of two location polynomial product Eq (23B). Since the GF(x) differentiation is difficult to carry out, as can be demonstrated with a simple example given by:

Ψ(x)=α⁶+α⁵x+α⁶x²+αx³,

Ψ′(x)=0+α⁵+0+αx²,

odd xⁿ coefficient of Ψ(x) need to be extracted and the original coefficients copied down as one order down Xⁿ⁻¹, since even xⁿ must be zero by GF algebra; However this differentiation is difficult for hardware ASIC to implement;

For simple calculation without involving differential of Ψ(x), the syndrome calculation is repeated again based on Eq. (23A), and the same algorithm is applied to find sets of S₀, S₁, S₂, S₃ on Eq. (23A) to determine Xⁱ, X^{j} and corresponding fail bytes fi and fj as disk crash byte values.

C(x)=rₛᵤₚ(x)+X^{X1}*Y₁+fᵢ*Xⁱ+fⱼ*X^{j}; Eq. (23K)

where rₛᵤₚ(x) is obtained from Eq. (23F) by suppressing failing disk terms. C(X) is correct bytes that should be returned to the host as requested value.

Failing disks may be known easily once diagnosed, before the host talks to the SD Array. Once it is known which disk is failing, an erasure disk number is reported to the RS algorithm if flash memory sector ECC (or sector parity on each page within flash memory block) is not consistent with sector data.

### (4) Four Disk Crash Case:

Initially two disk crash positions are calculated and crash bytes are found by suppressing other two disk positions by zeroing out.

Then same theory is applied again to find out the rest of two disk crash byte values again. This is easier understood by an example:

c(x)=α⁴x⁶+α⁵x⁵+α²x⁴)+α⁴x³+α²x²+α³x+α²; Eq. (23D)

where c(x) is the golden code without any errors, and parenthesis contains the message data disk value.

Assuming f1, f2, f3, f4, i.e. four disks have failed (underlined), and rₛᵤₚ(x) is received as the partial value besides the four disk crash cases that have already occurred.

S₁(x)=rₛᵤₚ(x)=α⁴x⁶+α⁵x⁵+0+0+0+0+α²; Eq. (24)

1^{st} syndrome value S₁(x) may be obtained as

r_{sup 0}(1)=α⁶; Eq. (24A)

r_{sup 1}(α)=α²; Eq. (24B)

r_{sup 2}(α²)=α; Eq. (24C)

r_{sup 3}(α³)=α³; Eq. (24D)

where disk crash location polynomial equals

$$\begin{matrix}Γ ( x ) = Π ( 1 - {a}^{i} x ) = ( 1 + α x ) * ( 1 + {α}^{2} x ) * \\ ( 1 + {α}^{3} x ) * ( 1 + {α}^{4} x ) \\ = ( 1 + {α}^{4} x + {α}^{3} {x}^{2} ) * ( 1 + {α}^{6} x + {x}^{2} ) \\ = {α}^{3} {x}^{4} + α {x}^{3} + {x}^{2} + {α}^{3} x + 1 ;\end{matrix} \qquad Eq . ( 24 E )$$

where i reflects four disk crash position inversions for example disk 3 is α³ and disk 4 is α⁴, and 2^{nd} syndrome S(x) is given by:

$$\begin{matrix} \begin{matrix}{S}_{2} ( x ) = [ Γ ( x ) * ( {r}_{sup 0} + {r}_{sup 1} x + {r}_{sup 2} {x}^{2} + {r}_{sup 3} {x}^{3} ) ] \\ = mod {x}^{4} [ ( {α}^{3} {x}^{4} + α {x}^{3} + {x}^{2} + {α}^{3} x + 1 ) * \\ ( {α}^{6} + {α}^{2} x + α {x}^{2} + {α}^{3} {x}^{3} ) ] mod {x}^{4} \\ = {α}^{6} ;\end{matrix} & Eq . ( 24 F ) \\ {Γ}^{′} ( x ) = d [ {α}^{3} * ( 1 / α + x ) * ( 1 / {α}^{2} + x ) * ( 1 / {α}^{3} + x ) * ( 1 / {α}^{4} + x ) ] / dx , & Eq . ( 24 G )\end{matrix}$$

Γ′(x)=α³*/ΣΠ_{β≠γ}(1/β−1/γ), (24H),

x is location of crash disk position,
for example:

Γ′(α)=α³*/(1/α−1/α²)*(1/α−1/α³)*(1/α−1/α⁴);

Γ′(α²)=α³*/(1/α−1/α²)*(1/α²−1/α³)*(1/α²−1/α⁴);

Γ′(α³)=α³*/(1/α³−1/α²)*(1/α³−1/α)*(1/α³−1/α⁴);

Γ′(α⁴)=α³*/(1/α⁴−1/α²)*(1/α⁴−1/α³)*(1/α⁴−1/α);

and fⱼ=[α^{j}*S(α^{j})]/Γ′(x) (24I),

where β, γ are location of the four disk crash locations, fⱼ is each disk error magnitude recovered.

f₁=(α*α⁶)/α⁴=α³;

f₂=(α²*α⁶)/α⁶=α²;

f₃=(α³*α⁶)/α⁵=α⁴;

f₄=(α⁴*α⁶)/α=α²;

and e(x)=f₁x+f₂x+f₃x+f₄x

=α³x+α²x²+α⁴x³+α²x⁴;

adding to Eq (24)

rₛᵤₚ(x)=α⁴x⁶+α⁵x⁵+0+0+0+0+α²; Eq. (24)

adding e(x) it is found that

c(x)=α⁴x⁶+α⁵x⁵+α²x⁴+α⁴x³+α²x²+α³x+α²; Eq. (23D)

where c(x) is golden code without any errors.
Apparently, the differential value is needed to be calculated so as to find Γ′(x), however it is only needed to feed into the error locations reported back by the host,

$${Γ}^{′} ( x ) = {α}^{3} * / ( 1 / x - 1 / {α}^{2} ) * ( 1 / x - 1 / {α}^{3} ) * ( 1 / x - 1 / {α}^{4} ) + {α}^{3} * / ( 1 / x - 1 / {α}^{2} ) * ( 1 / x - 1 / {α}^{3} ) * ( 1 / x - 1 / {α}^{4} ) + {α}^{3} * / ( 1 / x - 1 / {α}^{2} ) * ( 1 / x - 1 / α ) * ( 1 / x - 1 / {α}^{4} ) + {α}^{3} * / ( 1 / x - 1 / {α}^{2} ) * ( 1 / x - 1 / {α}^{3} ) * ( 1 / x - 1 / α ) ; \qquad Eq . ( 24 J ) ,$$

It may be done with a table look up, or simple logic addition can fulfill the task.

Although the present invention has been described in terms of specific embodiment, it is anticipated that alterations and modifications thereof will no doubt become apparent to those more skilled in the art. It is therefore intended that the following claims be interpreted as covering all such alterations and modification as fall within the true spirit and scope of the invention.

What is claimed is:

1. An electronic data storage device comprising:
A Reed Solomon (RS) decoder including,
a syndrome calculator block responsive to information including data and overhead and operative to generate a syndrome;
a root finder block coupled to receive said syndrome and operative to generate at least two roots, said RS decoder for processing said two roots to generate at least one error address identifying a location in said data wherein said error lies; and
an erasure syndrome calculator block responsive to said information and operative to generate an erasure syndrome, said RS decoder responsive to said information identifying a disk crash, said RS decoder for processing said erasure syndrome to generate an erasure error to recover the data in said disk crash.

2. An electronic data storage device as recited in claim 1 being a flash memory storage solid state disk (SSD) including one or more storage disks for storing said data, said flash memory storage (SSD) further including one or more Reed Solomon (RS) parity storage disks for storing said overhead used by said RS decoder for error detection and recovery.

3. An electronic data storage device as recited in claim 2 being coupled to a host for transfer of said information therebetween, said host operative to write and read said information onto and from said flash memory storage solid state disk for storage therein, said host further operative to notify said flash memory storage solid state disk of one or more crashed disks, said Reed Solomon (RS) decoder operative to recover the data in said one or more crashed disks.

4. An electronic data storage device as recited in claim 3 further including a central controller having a Reed Solomon (RS) algorithm coupled to receive said information, said electronic data storage device further including an RS calculating unit coupled to said controller and operative to decode said data using said RS algorithm.

5. An electronic data storage device as recited in claim 4 wherein said Reed Solomon (RS) calculating unit further including an RS encoder coupled to said central controller and operative to generate RS parity bytes for storage in said parity storage disks, said RS decoder operative to use said RS parity bytes to detect errors and recover data in said crashed disk.

6. An electronic data storage device as recited in claim 5 further including a data stripping unit coupled to receive said information and operative to divide said data and overhead into parts to generate a block length data including data parts, said parts being distributed between said storage disks and said Reed Solomon (RS) parity storage disks to allow said RS calculation unit to decode said data parts in parallel to reduce the delay time.

7. An electronic data storage device as recited in claim 6 wherein said block length data includes a plurality of sectors, said central controller including a direct memory access (DMA) engine coupled to receive a sector of said block length data and operative to transfer said sector to a buffer for storage, said DMA engine operative to fetch related sectors of said block length data for storage in temporary locations to allow said Reed Solomon (RS) calculating unit to generate RS parity bytes.

8. An electronic data storage device as recited in claim 7 wherein said storage disk includes a local controller coupled to receive said information and operative to detect and correct errors therein, said local controller including a Reed Solomon (RS) decoder operative to generate calculated RS parity bytes to detect and correct said errors.

9. An electronic data storage device as recited in claim 8 wherein said local controller operative to compare said calculated Reed Solomon (RS) parity bytes with said RS parity bytes to determine compatibility, said local controller operative to inform said host of said crashed disk, said RS calculating unit operative to recover the lost data in said crashed disk.

10. An electronic data storage device as recited in claim 9 wherein said Reed Solomon (RS) calculating unit being responsive to a receiving polynomial r(x) and operative to generate an error polynomial e(x), said RS decoder operative to generate a correct codeword c(x) according to
c(x)=r(x)+e(x).

11. An electronic data storage device as recited in claim 10 wherein said Reed Solomon (RS) decoder operative to set the terms in said receiving polynomial r(x) corresponding to crashed disk value equal to zero to generate rₛᵤₚ(x), said RS decoder operative to generate temporary syndromes from said rₛᵤₚ(x).

12. An electronic data storage device as recited in claim 11 wherein said Reed Solomon (RS) decoder operative to generate a disk crash location polynomial Γ(x), said RS decoder further operative to combine said Γ(x) with said rₛᵤₚ(x) to generate a syndrome.

13. An electronic data storage device as recited in claim 12 wherein said Reed Solomon (RS) decoder operative to generate r_{newsup}(x) and whole error position polynomial, said RS decoder operative to combine said r_{newsup}(x) and said whole error position polynomial to generate an erasure syndrome.

14. An electronic data storage device as recited in claim 1 being a redundant array of independent disks (RAID).

15. An electronic data storage device as recited in claim 1 wherein said Reed Solomon (RS) decoder operative to correct up to at least two bytes of error in one page, each page being 512 bytes of data area and 16 bytes of spare area wherein the plurality of data sections is three.

16. An electronic data storage device as recited in claim 1 wherein said Reed Solomon (RS) decoder including a root finder block to generate roots based upon the following equation:
Z²+Z+K=0.

17. A method of detecting and correcting errors employed in an electronic data storage device comprising:
receiving information including data and overhead;
generating a syndrome;
generating at least two roots;
processing the two roots to generate at least one error address;
identifying a location in the data wherein the error lies;
generating an erasure syndrome;
identifying a crashed disk; and
processing the erasure syndrome to generate an erasure error to recover the data in the crashed disk.
